(19) United States
(12) Patent Application Publication
(10) Pub. No.: US 2026/0114020 A1
(43) Pub. Date: Apr. 23, 2026

(54) N- AND P-TYPE 2D CHANNELS VIA SURFACE CHARGE TRANSFER FROM A DOPED OXIDE

(71) Applicant: SAMSUNG ELECTRONICS CO., LTD., Suwon-si (KR)

(72) Inventors: Nikhil SIVADAS, Lexington, MA (US); Yongwoo SHIN, Concord, MA (US)

(73) Assignee: SAMSUNG ELECTRONICS CO., LTD., Suwon-si (KR)

(21) Appl. No.: 19/075,346

(22) Filed: Mar. 10, 2025

Related U.S. Application Data
(60) Provisional application No. 63/710,442, filed on Oct. 22, 2024.

(51) Int. Cl. H10D 64/68; C01B 33/12; C01G 25/02; C01G 27/02; H01L 21/3115

(52) U.S. Cl. CPC H10D 64/691; C01B 33/12; C01G 25/02; C01G 27/02; H10P 32/20; C01P 2002/54; C01P 2006/40

(57) ABSTRACT

A doped binary oxide high-k gate dielectric has the following formula M₁₋ₓNₓO₂, wherein M═Hf, Zr, or Si, N═Ta, Nb, Re, Os, or Ru, and 0<x<0.2, or the following formula M₁₋ₓPₓO₂, wherein M═Hf, Zr, or Si, P═Co, Bi, Fe, Y, Al, or B, and 0<x<0.2. A method for doping a transition metal dichalcogenide layer includes doping a binary oxide high-k gate dielectric layer to provide the aforementioned doped binary oxide high-k gate dielectric and thereby dope the transition metal dichalcogenide layer by surface charge transfer doping.

### CROSS-REFERENCE TO RELATED APPLICATIONS

This application is based on and claims priority from U.S. Provisional Application No. 63/710,442 filed on Oct. 22, 2024 in the U.S. Patent and Trademark Office, the disclosure of which is incorporated herein by reference in its entirety.

### BACKGROUND

### 1. Field

The subject matter disclosed herein relates to a doped binary oxide high-k gate dielectric of the following formula M₁₋ₓNₓO₂, wherein M═Hf, Zr, or Si, N═Ta, Nb, Re, Os, or Ru, and 0<x<0.2, or the following formula M₁₋ₓPₓO₂, wherein M═Hf, Zr, or Si, P═Co, Bi, Fe, Y, Al, or B, and 0<x<0.2.

### 2. Description of the Related Art

The use of high-k dielectrics is crucial for reducing the effective oxide thickness in transistors, which in turn allows for smaller and faster device performance. In this regard, the metronomic progress in CMOS transistor density and switching energy over time is shown in FIG. 1.

The performance of Si-based transistors degrades significantly as the channel thickness is reduced below 4 nm. This limits the application of Si-based transistors for making next-generation transistors that are atomically thin and thereby are faster and more energy efficient.

To make a transistor such as the one shown in FIG. 2 smaller, one approach is geometry scaling, which makes everything in the transistor smaller. Another approach is equivalent scaling, which uses other oxides instead of SiO₂, where those other oxides have a lower equivalent oxide thickness (EOT) than SiO₂ (that is, oxides which, when used in a smaller layer thickness than SiO₂, can give the same device metrics as with SiO₂). In particular, by using high-k materials (e.g., HfO₂), EOT can be lowered.

Compared to Si-based transistors (SOI in FIG. 3), transition metal dichalcogenide (TMD)-based semiconducting van der Waal's materials (MX₂, M═Mo, W; X═S, Se) show robust mobility for channels having an atomically thin layer thickness. Further, as they have a layered structure and the different layers are held together with weak forces, these materials are stable in the monolayer limit with no dangling bonds that can degrade device performance.

For further showing feasibility of TMDs as alternative channel material to Si, the ability to provide both n-doped and p-doped TMD is needed. TMDs like MoS₂ naturally form in n-doped. However, controlling the dopant concentration is an important step for device fabrication.

Substitution doping of Re of Mo has been proposed to n-dope MoS₂. However, higher concentration of dopants could make these layers metallic, leading to a short circuit. Further, by design, this approach creates more scattering centers in the channel layer which could affect the mobility of electrons.

Another approach is to use surface charge transfer doping (SCTD) between an organic molecule adsorbate and the TMD layer which naturally occurs for appropriate band alignment (see FIG. 4: The Ionization energy, IE of organic layer is smaller than the electron affinity, EA, of TMDs). Unlike substitution doping, this approach does not degrade the crystal quality. However, adding organic molecules to transistors could lead to engineering challenges like thermal stability and scalability.

The inorganic gate oxide layer that is ever present in a transistor geometry could also lead to SCTD of TMDs.

However, reliable strategies to both p-dope and n-dope TMDs have been largely lacking.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

An object of the disclosure is to provide a new strategy to n-dope and p-dope transition metal dichalcogenides.

By appropriately doping the high-k layer, the present disclosure can achieve n-doping and p-doping of the nearby TMD layer while reducing the SOP that limit the mobility of the TMD layer.

In particular, the present disclosure provides a list of chemistries to n-dope and p-dope transition metal dichalcogenides (TMDs: MoS₂, WSe₂, MoSe₂, WS₂) using a binary oxide high-k gate dielectric like HfO₂, ZrO₂, or SiO₂ and chemical combinations of them by n-doping the oxide layer with {Ta, Nb, Re, Os, Ru} within the fractional (x) limit 0<x<0.2 or by p-doping the oxide layer with {Co, Bi, Fe, Y, Al, B} within the fractional (x) limit 0<x<0.2.

The present disclosure allows to n-dope or p-dope TMDs using the existing geometry of gate dielectrics without degrading the device performance by reducing scattering mechanisms while retaining the high-dielectric behavior.

Advantages of the present disclosure include no need for substitution doping of TMDs to n-dope or p-dope. Substitution doping can degrade the device performance as it is creating more defects within the channel. The present approach is a non-invasive approach for doping the channel. Further, the good features (large dielectric values) of having a high-k dielectric are retained within the fractional doping specified in the present disclosure, while the negative attributes (scattering via surface phonons) are also potentially mitigated.

Thus, the present disclosure includes the following embodiments.

A first embodiment of the present disclosure provides a doped binary oxide high-k gate dielectric of the following formula (1):

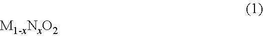

wherein M═Hf, Zr, or Si, N═Ta, Nb, Re, Os, or Ru, and 0<x<0.2,
or the following formula (2):

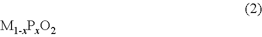

wherein M═Hf, Zr, or Si, P═Co, Bi, Fe, Y, Al, or B, and 0<x<0.2.

A second embodiment of the present disclosure provides a doped binary oxide high-k gate dielectric of the first embodiment, wherein the doped binary oxide high-k gate dielectric is a doped binary oxide high-k gate dielectric of formula (1).

A third embodiment of the present disclosure provides a doped binary oxide high-k gate dielectric of the second embodiment, wherein N═Ta.

A fourth embodiment of the present disclosure provides a doped binary oxide high-k gate dielectric of the second embodiment, wherein N═Nb.

A fifth embodiment of the present disclosure provides a doped binary oxide high-k gate dielectric of the second embodiment, wherein N═Re.

A sixth embodiment of the present disclosure provides a doped binary oxide high-k gate dielectric of the second embodiment, wherein N═Os.

A seventh embodiment of the present disclosure provides a doped binary oxide high-k gate dielectric of the second embodiment, wherein N═Ru.

A eighth embodiment of the present disclosure provides a doped binary oxide high-k gate dielectric of the first embodiment, wherein the doped binary oxide high-k gate dielectric is a doped binary oxide high-k gate dielectric of formula (2).

A ninth embodiment of the present disclosure provides a doped binary oxide high-k gate dielectric of the eighth embodiment, wherein P═Co, Bi, or Fe.

A tenth embodiment of the present disclosure provides a doped binary oxide high-k gate dielectric of the eighth embodiment, wherein P═Co.

An eleventh embodiment of the present disclosure provides a doped binary oxide high-k gate dielectric of the eighth embodiment, wherein P═Bi.

A twelfth embodiment of the present disclosure provides a doped binary oxide high-k gate dielectric of the eighth embodiment, wherein P═Fe.

A thirteenth embodiment of the present disclosure provides a doped binary oxide high-k gate dielectric of the second embodiment, wherein M═Hf.

A fourteenth embodiment of the present disclosure provides a doped binary oxide high-k gate dielectric of the eighth embodiment, wherein M═Hf.

A fifteenth embodiment of the present disclosure provides a doped binary oxide high-k gate dielectric of the ninth embodiment, wherein M═Hf.

A sixteenth embodiment of the present disclosure provides a method for doping a transition metal dichalcogenide layer, comprising doping a binary oxide high-k gate dielectric layer to provide a doped binary oxide high-k gate dielectric of the first embodiment and thereby dope the transition metal dichalcogenide layer by surface charge transfer doping.

A seventeenth embodiment of the present disclosure provides a method of the sixteenth embodiment, wherein the method is a method for n-doping a transition metal dichalcogenide layer, comprising doping a binary oxide high-k gate dielectric layer to provide a doped binary oxide high-k gate dielectric of formula (1) and thereby n-dope the transition metal dichalcogenide layer by surface charge transfer doping.

An eighteenth embodiment of the present disclosure provides a method of the sixteenth embodiment, wherein the method is a method for p-doping a transition metal dichalcogenide layer, comprising doping a binary oxide high-k gate dielectric layer to provide a doped binary oxide high-k gate dielectric of formula (2) and thereby p-dope the transition metal dichalcogenide layer by surface charge transfer doping.

A nineteenth embodiment of the present disclosure provides a method of the eighteenth embodiment, wherein P═Co, Bi, or Fe.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Example embodiments of the present disclosure will be more clearly understood from the following detailed description taken in conjunction with the accompanying drawings in which:

FIG. 1 is a graph showing the metronomic progress in CMOS transistor density and switching energy over time.

FIG. 2 shows a representative transistor structure.

FIG. 3 is a graph showing the mobility (μ) of electrons as a function of channel thickness (t_{CH}), and illustrates that for Si on insulators (SOI), the mobility degrades when t_{CH} is below 4 nm, while transition metal dichalcogenides (MoS₂, WSe₂, etc.) show robust mobility for thinner channels.

FIG. 4 is a schematic energy level diagram of surface charge transfer doping (SCTD) between organic molecules and MoS₂, and illustrates depletion and a n-doping process via SCTD of organic molecules with higher electron affinity (EA) than the ionization energy (IE) of TMDs.

FIG. 5 shows graphs considering TMD interfaced with Hf₍₁₋ₓ₎MₓO₂ where the interface HfO₂ layer is replaced by MO₂ layer (results in this figure are for the interface and show n-doping of WSe₂, in blue).

FIGS. 6A-6F show larger versions of the subfigures of FIG. 5.

FIG. 7A is a graph showing the charge transferred to the TMD layer for various n-dopants to dope Hf in an HfO₂ interface layer, and FIG. 7B is a graph showing the charge transferred to the TMD layer for various p-dopants to dope Hf in an HfO₂ interface layer.

FIG. 8 shows the estimated ionization energy (vacuum level set as zero-reference) of typical oxides used as dielectrics.

FIGS. 9A-9E are supplemental graphs showing the density of states vs. energies for various dopants.

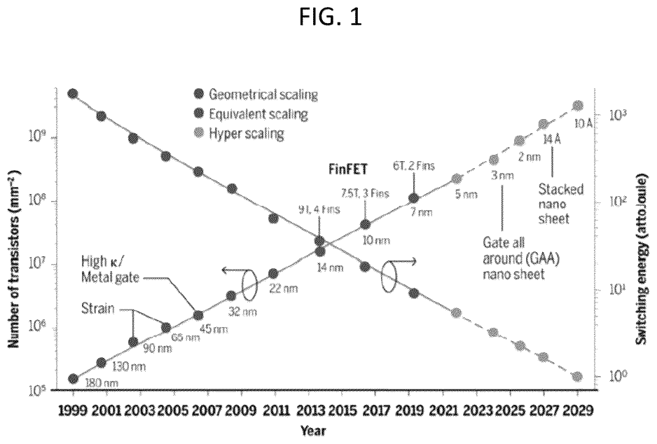

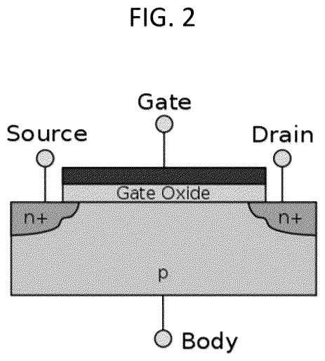

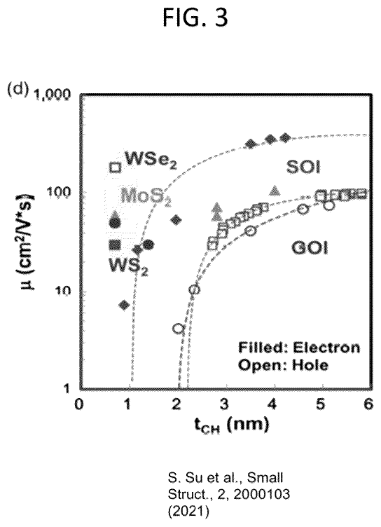

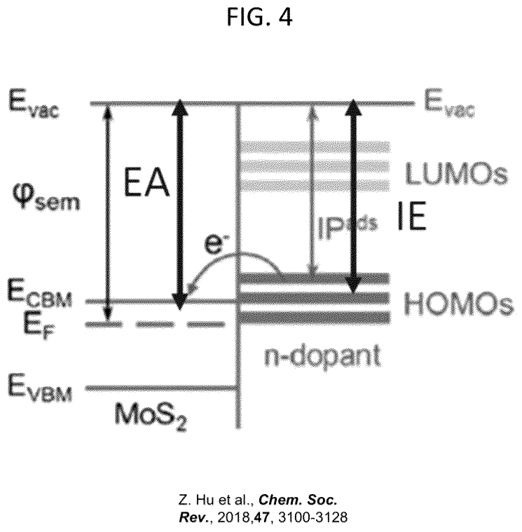

### DETAILED DESCRIPTION OF EXAMPLE EMBODIMENTS

As mentioned above, the present disclosure provides a list of chemistries to n-dope and p-dope transition metal dichalcogenides (TMDs: MoS₂, WSe₂, MoSe₂, WS₂) using a binary oxide high-k gate dielectric like HfO₂, ZrO₂, or SiO₂ and chemical combinations of them by n-doping the oxide layer with {Ta, Nb, Re, Os, Ru} within the fractional (x) limit 0<x<0.2 or by p-doping the oxide layer with {Co, Bi, Fe, Y, Al, B} within the fractional (x) limit 0<x<0.2.

HfO₂ is a well studied high-k dielectric binary oxide. The band alignment of HfO₂ is not directly favorable for substrate n-doping TMDs—the CBM of pristine HfO₂ is above the VBM of TMDs.

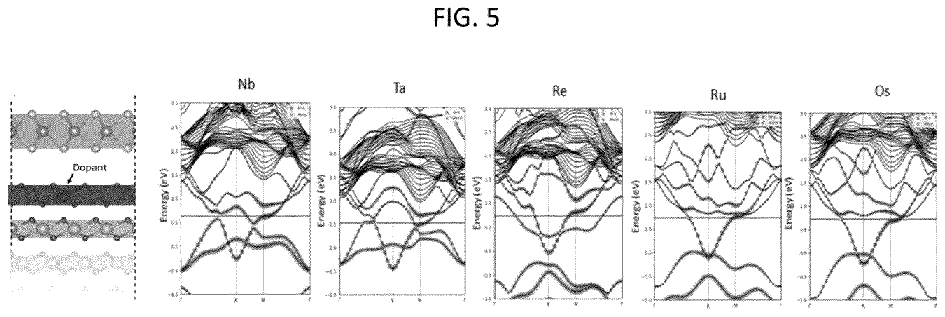

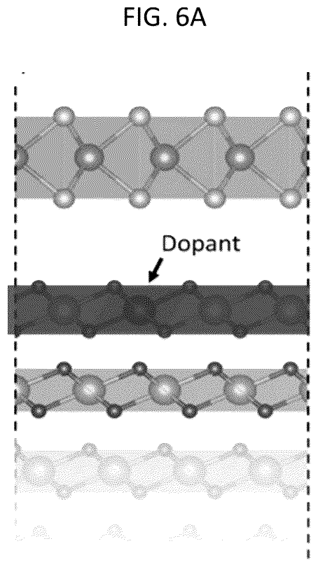

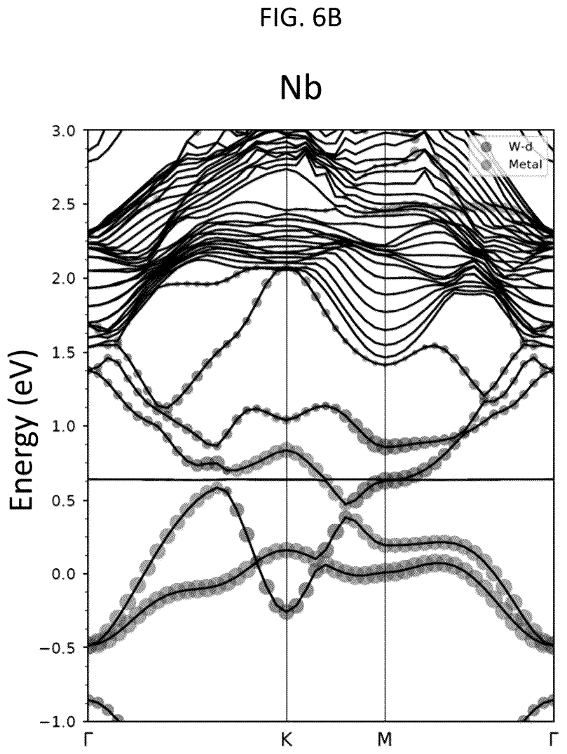

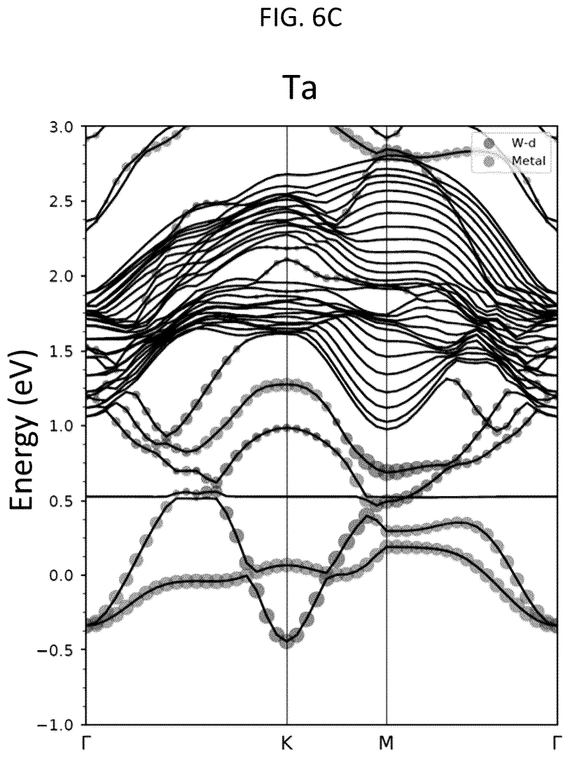

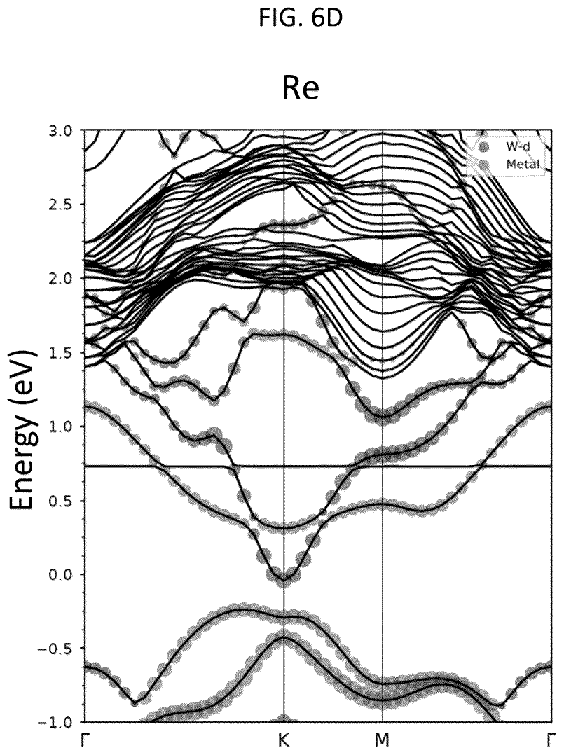

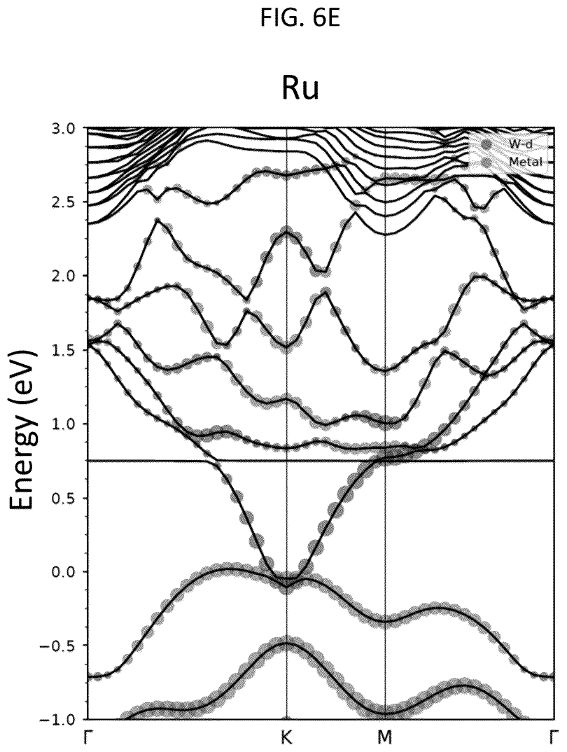

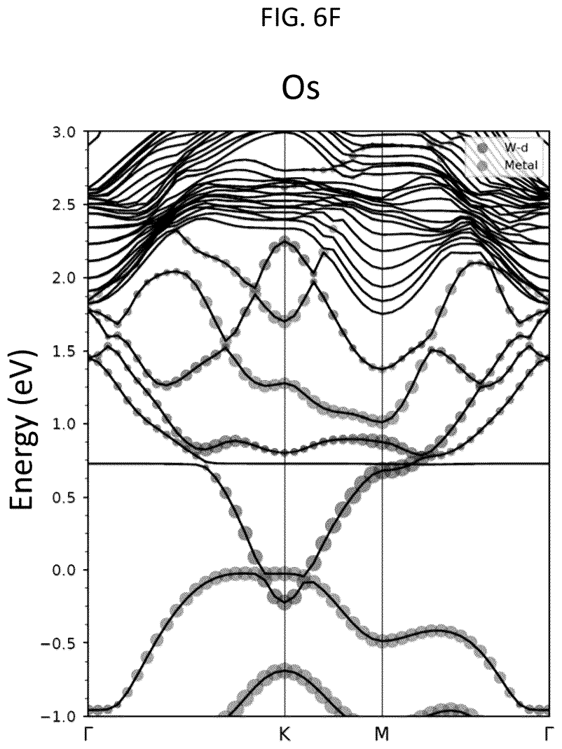

FIG. 5 shows graphs considering TMD interfaced with Hf (1-x) MₓO₂ where the interface HfO₂ layer is replaced by MO₂ layer (results in this figure are for WSe₂). The subfigures in FIG. 5 are shown individually in FIGS. 6A-6F. The band alignment of Hf (1-x) MₓO₂ interfaced with WSe₂ shows that the CBM of TMD layer is occupied, thereby doping the TMD layer. The charge is transferred from the interface TMD layer.

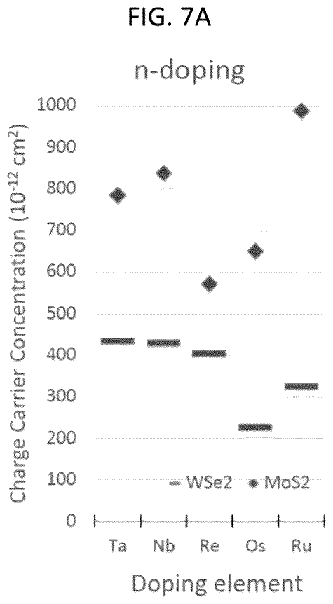

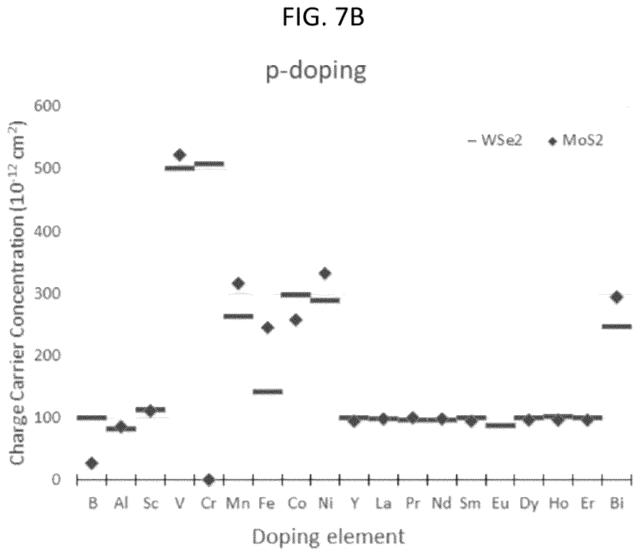

FIGS. 7A and 7B show the charge transferred to the TMD layer for various dopant candidates to dope Hf in HfO₂ interface layer. In particular, FIG. 7A is a graph showing the charge transferred to the TMD layer for various n-dopants (Ta, Nb, Re, Os, Ru) to dope Hf in an HfO₂ interface layer, and FIG. 7B is a graph showing the charge transferred to the TMD layer for various p-dopants (Co, Bi, Fe, Y, Al, B) to dope Hf in an HfO₂ interface layer.

Thus, the present disclosure shows cation doping of HfO₂ with transition metals whose oxides lead to a charge transfer from the oxide layer to the TMD layer.

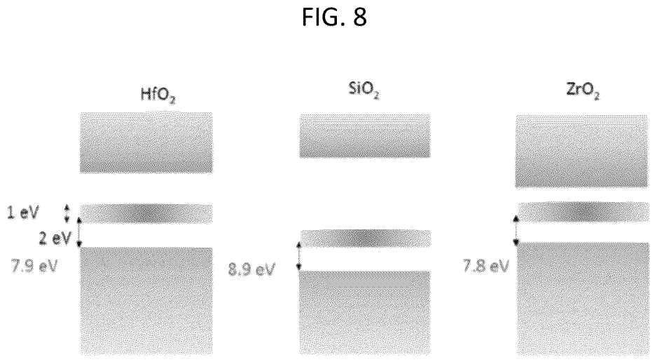

FIG. 8 shows the ionization energy of typical oxides used as dielectrics estimated by computing the vacuum levels and the valance bands of a monolayer slab of oxide. Assuming that the relative position of the dopant bands relative to the shared oxygen atoms are the same, the relative band shift between the different surfaces can be estimated by computing the ionization energies of the surfaces. Given that the dopant levels are lower (SiO₂) or similar (ZrO₂) in energy to HfO₂, they are expected to transfer electrons to TMD.

Thus, the results provided by the present disclosure reveal that the relative band alignment in conventional high-k oxides can be modified by the doping strategy of the present disclosure. This should result in n-doping or p-doping the neighboring TMD layer. For doping in the range 0<x<0.2, the dielectric constant of the high-k layer is expected to retained with 80% accuracy.

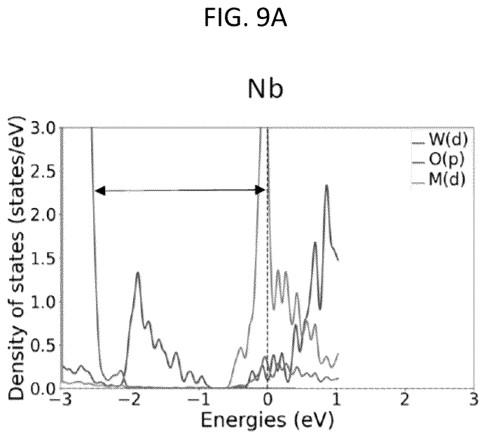

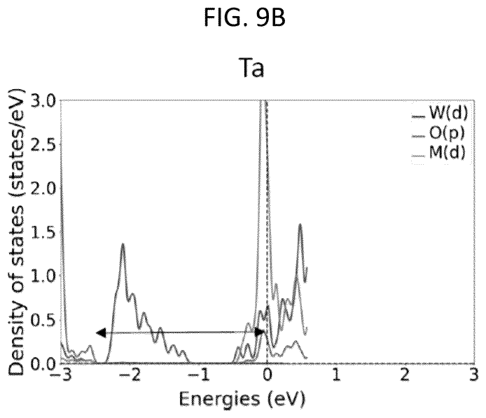

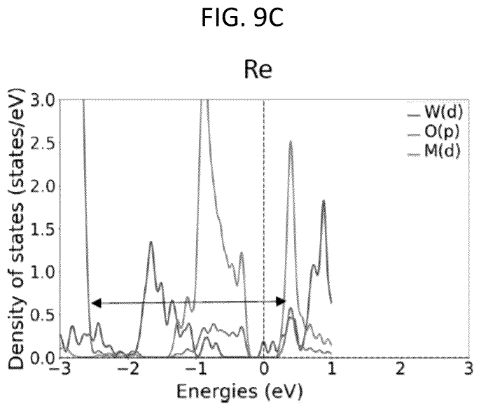

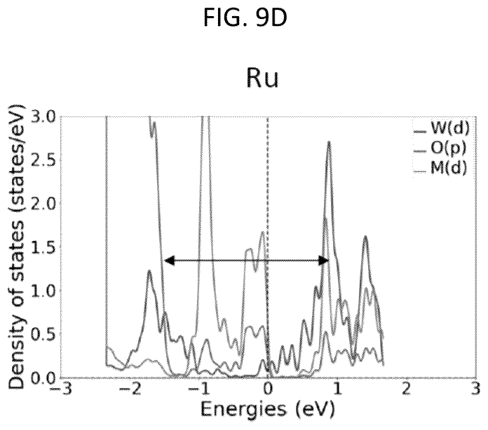

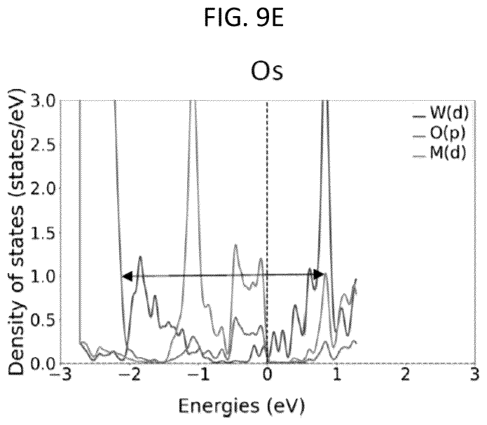

As supplemental information, FIGS. 9A-9E are graphs showing the density of states vs. energies for various dopants, namely, the n-dopants Nb, Ta, Re, Ru, and Os, respectively.

The atomic doping of the high-k layer in the present disclosure can be achieved using typical growth methods like thermal oxidation, atomic layer deposition, pulsed laser deposition, chemical vapor deposition, plasma oxidation, wet anodization or other chemical treatments.

By carrying out a method like one of the above methods, a structure of the present disclosure can be obtained.

The present disclosure can be used to improve the performance of existing transistors by integrating atomically thin 2D materials as channel layers.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A doped binary oxide high-k gate dielectric of the following formula (1): 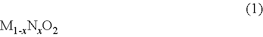
wherein M═Hf, Zr, or Si, N═Ta, Nb, Re, Os, or Ru, and 0<x<0.2,
or the following formula (2): 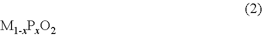
wherein M═Hf, Zr, or Si, P═Co, Bi, Fe, Y, Al, or B, and 0<x<0.2.

2. The doped binary oxide high-k gate dielectric of claim 1, wherein the doped binary oxide high-k gate dielectric is a doped binary oxide high-k gate dielectric of formula (1).

3. The doped binary oxide high-k gate dielectric of claim 2, wherein N═Ta.

4. The doped binary oxide high-k gate dielectric of claim 2, wherein N═Nb.

5. The doped binary oxide high-k gate dielectric of claim 2, wherein N═Re.

6. The doped binary oxide high-k gate dielectric of claim 2, wherein N═Os.

7. The doped binary oxide high-k gate dielectric of claim 2, wherein N═Ru.

8. The doped binary oxide high-k gate dielectric of claim 1, wherein the doped binary oxide high-k gate dielectric is a doped binary oxide high-k gate dielectric of formula (2).

9. The doped binary oxide high-k gate dielectric of claim 8, wherein P═Co, Bi, or Fe.

10. The doped binary oxide high-k gate dielectric of claim 8, wherein P═Co.

11. The doped binary oxide high-k gate dielectric of claim 8, wherein P═Bi.

12. The doped binary oxide high-k gate dielectric of claim 8, wherein P═Fe.

13. The doped binary oxide high-k gate dielectric of claim 2, wherein M═Hf.

14. The doped binary oxide high-k gate dielectric of claim 8, wherein M═Hf.

15. The doped binary oxide high-k gate dielectric of claim 9, wherein M═Hf.

16. A method for doping a transition metal dichalcogenide layer, comprising doping a binary oxide high-k gate dielectric layer to provide a doped binary oxide high-k gate dielectric of claim 1 and thereby dope the transition metal dichalcogenide layer by surface charge transfer doping.

17. The method of claim 16, wherein the method is a method for n-doping a transition metal dichalcogenide layer, comprising doping a binary oxide high-k gate dielectric layer to provide a doped binary oxide high-k gate dielectric of formula (1) and thereby n-dope the transition metal dichalcogenide layer by surface charge transfer doping.

18. The method of claim 16, wherein the method is a method for p-doping a transition metal dichalcogenide layer, comprising doping a binary oxide high-k gate dielectric layer to provide a doped binary oxide high-k gate dielectric of formula (2) and thereby p-dope the transition metal dichalcogenide layer by surface charge transfer doping.

19. The method of claim 18, wherein P═Co, Bi, or Fe.
